(19) United States
(12) Patent Application Publication
(10) Pub. No.: US 2005/0047071 A1
(43) Pub. Date: Mar. 3, 2005

(54) Wireless transmission interface and method

(76) Inventor: Bobby Tse Chun Hin, Hong Kong (HK)

Correspondence Address: MORGAN, LEWIS & BOCKIUS, LLP., 2 PALO ALTO SQUARE, 3000 EL CAMINO REAL, PALO ALTO, CA, 94306, US

(21) Appl. No.: 10/649,103

(22) Filed: Aug. 26, 2003

(51) Int. Cl. H05K 5/00

(52) U.S. Cl. 361/683

(57) ABSTRACT

A wireless interface is provided for coupling an audio player having a digital flash memory to an in-car audio system. The interface comprises a holder having a power plug adapted to an in-car cigarette lighter, a restraint for the audio player, and an FM transmitter for broadcasting the audio signal to the usual in-car FM radio. The device permits audio in the flash memory to be played on the in-car system, and provides a convenient means of holding the audio player for touch operation.

### FIELD OF THE INVENTION

This invention relates to a wireless interface for coupling an audio signal to a car audio system, and a related method. The invention more particularly relates to a holder for a portable audio player adapted to a compressed audio format, that is capable of insertion into a vehicle cigarette lighter socket.

### BACKGROUND TO THE INVENTION

Current personal audio systems use digital compression techniques to store music in a flash memory. Such systems typically use MP3 or WMA compression formats. The music is input digitally to the flash memory from, for example, a personal computer or via the Internet. It will be understood that, in contrast to CD or cassette based systems, the music is often integrated in the audio player. In other words there is no separable medium on which the recorded music can be removed for playback on another audio player.

The digital compression techniques permit MP3/WMA players to be very small, typically box-like and having dimensions of less than 60 mm×30 mm×20 mm. The limiting factor in size and shape is often related to the practical size of control buttons, connection parts and the usual LCD display.

Car audio systems usually comprise a radio and a CD or cassette player. Plainly an MP3 music file cannot be played through such systems directly, and it has been proposed to provide a connection lead for audio output of the MP3 player. Such leads are not practicable for some car audio systems, but if suitable usually comprise a power lead and an audio signal lead, each connecting to different parts of the car dashboard. These leads are long in order to be suitable for all kinds of vehicle, and can be considered dangerous if they obstruct the vehicle controls. Generally speaking, such connection leads are unreliable and very undesirable.

A further problem is that the small size of MP3 type players means that they may easily be damaged if merely plugged onto the end of connection leads in the vicinity of a car dashboard. Moreover, such an audio player does not have sufficient mass to overcome the natural resilience of the connection leads, and thus cannot be placed in a location suitable for convenient operation by the driver.

Nevertheless, users often wish to connect an MP3 player to a car audio system. What is required is a simple and convenient connection means which overcomes the aforementioned problems in a reliable manner and which is universally adaptable to all makes of car.

### SUMMARY OF THE INVENTION

According to the invention there is provided a holder for a portable audio player adapted to a compressed audio format, the holder comprising a body, a power transmitting plug extending from the body and adapted for insertion into a vehicle cigarette lighter socket, and the body having a restraint adapted to hold a portable audio player, the holder further including an FM transmitter, a first connection to couple the audio output of the audio player to the transmitter, and a second connection to couple the transmitter to the plug.

The holder according to the invention is thus adapted in use to make an FM transmission of the audio output of the audio player, so that the transmission can be received by the usual in-car FM radio. The second connection permits the FM transmitter to be powered by the vehicle electrical system through the plug. Audio players adapted to a compressed audio format, typically MP3 or WMA, are very small and thus capable of being supported on the holder by the extending plug. The invention also provides a safe and secure location for such very small audio players, and a means of supporting these players for touch operation.

In the preferred embodiment, the holder is comprised of one or more plastic mouldings assembled into a one-piece unit and having an interior space to house the transmitter and associated electrical connections. The restraint comprises any suitable construction adapted to hold the audio player on the holder.

Preferably the holder includes a third connection to couple the power supply of the audio player to the plug. Optionally the third connection may also couple to a charging unit for the audio player. The third connection thus permits the audio player to be powered and/or recharged via the vehicle electrical system.

The holder may further include a transformer to provide a suitable operating/recharging voltage to the audio player from the vehicle system voltage, for example 12V to 5V DC. The transmitter may also be adapted to the transformed voltage, and in the preferred embodiment is housed within the interior space.

The holder is preferably in the form of a cradle adapted to the shape of the audio player and having a front side exposing in use the audio player controls, and a rear side from which the plug extends. In the case of a rectangular box-like audio player, the cradle preferably comprises a ‘U’ shaped recess open at one side and adapted to retain the audio player in all directions except that of entry/exit. This direction is defined by a mouth, which in use is arranged at the top. The ‘U’ shaped recess comprises an open fronted slot, and the holder may further include a releasable latch to retain the audio player therein.

The invention also provides a method of playing in a vehicle, audio contained in a digital flash memory, the method comprising: providing a holder for apparatus containing a flash memory; providing the holder with an integral plug adapted for insertion into a vehicle cigarette lighter socket, providing an FM transmitter in the holder and powered via the plug, generating audio from the flash memory when on the holder, broadcasting the audio from the transmitter, receiving the audio on an FM radio, and playing the audio on loudspeakers connected to the FM radio.

In a preferred embodiment the method further includes one or more of the steps of: generating audio from the flash memory via an audio player adapted to MP3 or WMA formats, powering the audio player via the plug, and recharging the audio player via the plug.

The transmitter preferably has a low power, and an effective range of less than 1,000 mm.

In a further aspect, the invention provides a method of playing compressed digital audio in a vehicle comprising the steps of: coupling the audio to an FM transmitter, transmitting the audio on the FM waveband, receiving the audio on an in-car FM receiver, and playing the audio on in-car speakers.

The compressed digital audio is typically contained in a flash memory of an audio player adapted to one of MP3 and WMA formats.

### BRIEF DESCRIPTION OF THE DRAWINGS

Other features of the invention will be apparent from the following description of a preferred embodiment shown by way of example only in the accompanying drawings in which:

FIG. 1 illustrates front, back and end views of a conventional MP3 audio player.

FIGS. 2A and 2B illustrate in plan and elevation a cradle for the MP3 player of FIG. 1.

FIG. 3 illustrates four stages of coupling the player of FIG. 1 with the cradle of FIGS. 2A and 2B.

FIG. 4 is a block diagram showing component connections.

### DESCRIPTION OF PREFERRED EMBODIMENT

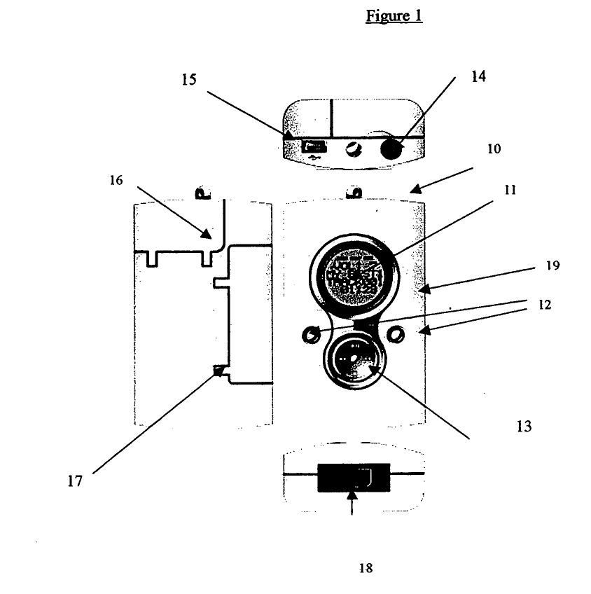

With reference to FIG. 1, a conventional portable audio player adapted to a compressed audio format 10 comprises a casing 19 housing a flash memory for storing compressed audio, typically music in a format such as MP3 or WMA. The casing 19 typically has one or more of the following: an external LCD display 11, audio volume control buttons 12, a general-purpose control button such as navigation key 13, a socket for an earphone plug 14, a USB socket 15 for connecting to another electronic device such as a personal computer, an SD/MMC expansion slot 16 for accepting additional removable flash-memory, and a battery compartment 17. Also included with a portable audio player for use with the present invention, is an expandable audio interface socket 18, details of which are given hereinbelow.

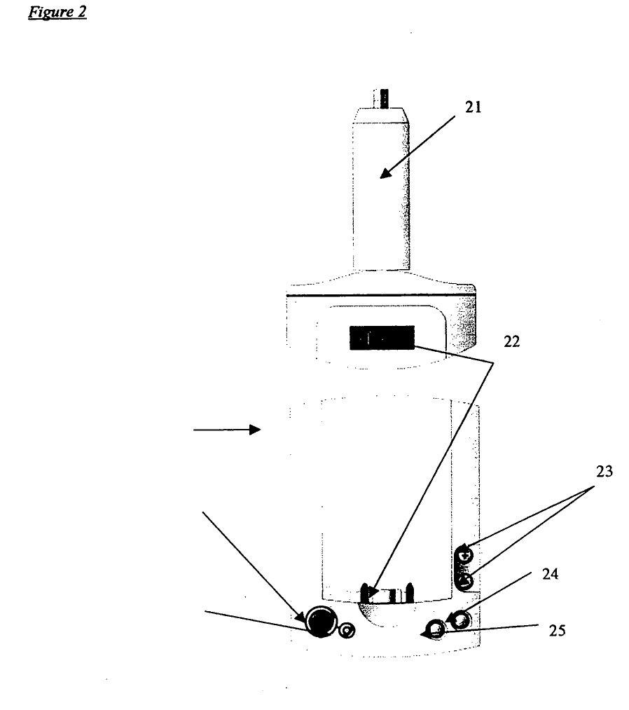

FIGS. 2A and 2B illustrate a preferred embodiment of a holder according to the present invention. The body of the holder comprises a restraint adapted to hold a portable audio player. In FIGS. 2A and 2B, the restraint takes the form of a cradle 20, for use with a player such as that of FIG. 1. The holder also comprises an adapter extension 21 for use with a conventional cigarette lighter socket of a motor vehicle. An automobile cigarette lighter socket can also be referred to as a cigar lighter socket in some places. In a preferred embodiment, Adapter extension 21 functions as a power transmitting plug.

The cradle 20 has a ‘U’ shaped recess in elevation (see FIG. 2B) which is adapted to receive the casing 19 and which has an expandable audio interface plug 22, for connection to the socket 18. It is to be understood that, although the audio interface 18 on casing 19 has been designated as a ‘socket’, and the audio interface 22 on the cradle as a ‘plug’, the plug and socket are interchangeable so that, for example, the audio interface on casing 19 could be a plug, and the audio interface 22 could be a socket. It is further to be understood that, although the plug 22 is shown in FIGS. 2A and 2B to be positioned in the center, bottom, of the ‘U’ shaped recess, alternate locations are consistent with the present invention, provided that they are capable of connecting with socket 18 on the casing 19 of the portable audio player. Such alternate locations of the plug 22 include offset from the center, at the bottom of the recess, or at the top of the recess, in the center, or to one side. The ‘U’ shaped recess is preferably open at one side, as shown in FIG. 2B, so that controls and/or a display on the audio player are visible or accessible to a user. The ‘U’ shaped recess is also adapted to retain the audio player except in the direction of entry/exit, such as at the top of the cradle shown in FIG. 2B.

The cradle has internal components to be further described below, and externally it preferably includes one or more of the following controls: one or more FM channel selection keys 23, one or more FM channel pre-set keys 24, an FM channel re-set key 25, a power indicator 26, and an on/off button or combination of buttons 27.

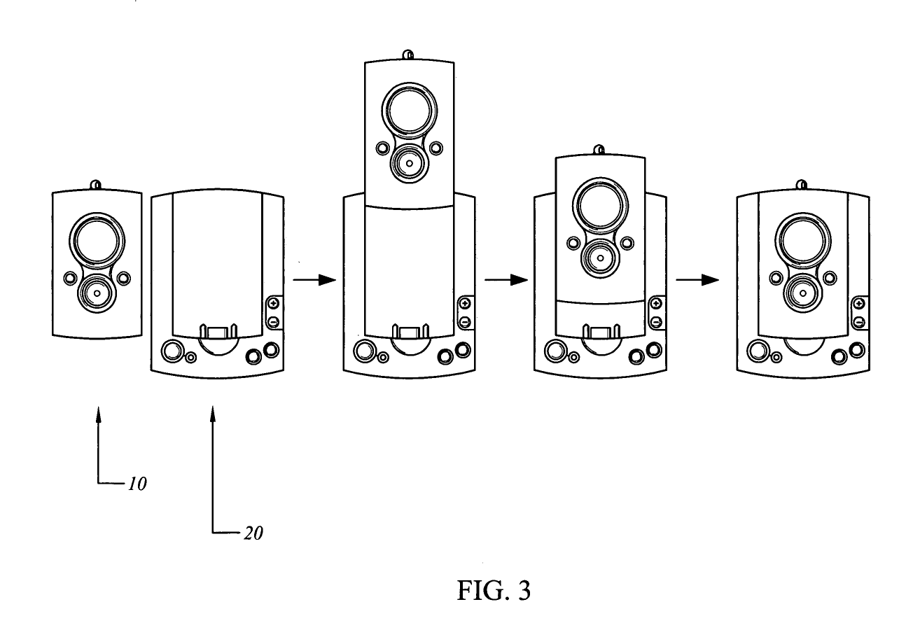

FIG. 3 illustrates four stages in slotting the casing 19 of audio player 10 into the cradle 20, thereby connecting the plug 22 and socket 18 to one another.

In use, the cradle 20 is preferably adapted to power and/or recharge the audio player 10 by connection to the vehicle electrical system via the extension 21 and the combination of plug 22 and socket 18. Within the cradle 20 is provided a radio frequency transmitter. If required, a suitable transformer can be incorporated in the cradle, typically to provide a 5V supply for the player 10 and the radio frequency transmitter. The audio analogue output from the player 10 also passes to the cradle via the plug/socket combination 22, 18.

The radio frequency transmitter within the cradle 20 is adapted to transmit the analogue output on the FM band, for example at a frequency selected by the FM channel selection keys 23. This broadcast is, in use, detectable by the usual in-car FM radio, and is playable via the car audio system. The power output of the transmitter is typically about 0 dBmw.

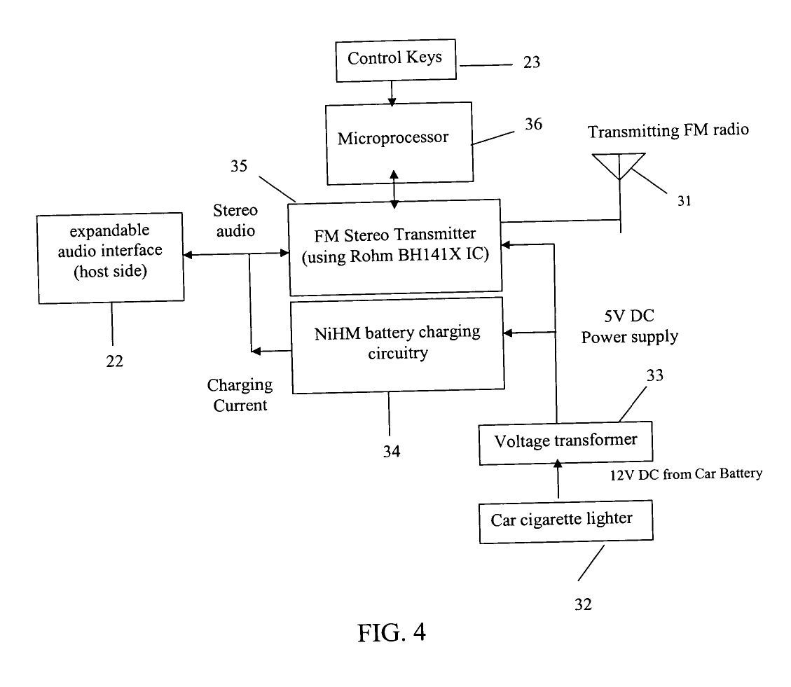

FIG. 4 is a block diagram illustrating component connections. It will be understood that the methods by which such connections may be made and installed in a holder 20 are within the knowledge and capability of one of ordinary skill in the art. FIG. 4 shows a car FM radio 31 which is adapted to receive signals from a conventional FM transmitter, for example a local music station. A cigarette lighter 32 typically has a 12V DC supply from the vehicle battery.

The cradle 20 includes a voltage transformer 33 having a 5V DC output, a battery charger 34 suitable for the rechargeable battery of the audio player 10, an FM transmitter 35 for transmitting to the radio 31, control keys (e.g., 23), a microprocessor 36 and the plug 22.

In use, the cradle of the present invention is simple to use, being semi-permanently located in the cigar lighter socket. There are no connection leads to obstruct other vehicle controls, and the cradle provides a safe and secure means of storing and supporting the audio player. It will be noted that the cradle also holds the player in such a way that operation of the controls is simple, convenient, and one-handed.

Operation is as follows. The player 10 is installed in the cradle 20, as in FIG. 3, which is inserted into the cigarette lighter socket 32. The power switch 27 is pressed “on” and the power indicator (LED), if present, illuminates. The car FM radio is switched on and tuned to an idle channel. The FM selection keys are then used to select a matching transmission frequency so that the audio output is played through the vehicle audio system. Preferably the transmitter is a stereo transmitter adapted to a stereo output of the player 10. The car radio may “find” the FM broadcast channel by use of a “seek” facility, as is familiar to one of ordinary skill in the art.

It will be understood that the range and power of the transmitter 35 can be quite low because the transmission distance is very small, usually much less than 1,000 mm (1,000 mm=1 m, about 3.25 ft.). The full range of car audio controls is preferably available to produce the required in-car sound. When the system is turned off the user simply removes the audio player, or the combined audio player and cradle. The audio player controls remain functional, and accordingly the user may select tracks etc., in the usual manner. The in-car audio system is unmodified and requires no re-set or adaptation for use with the present invention.

Although the invention has been described in relation to a preferred embodiment, it is not intended that the invention should be limited to this embodiment. Modifications within the spirit of the invention will be apparent to those skilled in the art, and the scope of the invention is to be limited only by the appended claims.

1. A holder for a portable audio player adapted to a compressed audio format, the holder comprising a body, a power transmitting plug extending from the body and adapted for insertion into a vehicle cigar lighter socket, and a restraint adapted to hold a portable audio player, said holder further including an FM transmitter, a first connection to couple the audio output of said audio player to said transmitter, and a second connection to couple said transmitter to said plug.

2. A holder according to claim 1, wherein said holder includes a third connection to couple the power supply of said audio player to said plug.

3. A holder according to claim 2, wherein said third connection also couples a charging unit for said audio player to said plug.

4. A holder according to claim 1, wherein said compressed audio format is in MP3 or WMA format.

5. A holder according to claim 1, further including a transformer to provide a pre-determined voltage for said audio player.

6. A holder according to claim 5, wherein said transformer is adapted to supply said transmitter.

7. A holder according to claim 1, in the form of a cradle adapted to the shape of an audio player, the cradle having a front side exposing in use the audio player controls, and a rear side from which said plug extends.

8. A holder according to claim 7, wherein said cradle comprises a ‘U’ shaped recess open at one side and adapted to retain the audio player except in the direction of entry/exit.

9. A holder according to claim 8, wherein said direction is defined by a mouth, which in use is arranged uppermost.

10. A holder according to claim 9, wherein said ‘U’ shaped recess comprises an open fronted slot.

11. A holder according to claim 1, and further including a releasable latch to retain an audio player therein.

12. A holder according to claim 1, wherein said transmitter has an effective range of less than 1,000 mm.

13. A method of playing, in a vehicle, audio contained in a digital flash memory, the method comprising:
providing a holder for apparatus containing said flash memory;
providing said holder with an integral plug adapted for insertion into a vehicle cigarette lighter socket;
providing an FM transmitter in said holder and powered via said plug;
generating audio from said flash memory when on said holder;
broadcasting said audio from said transmitter;
receiving said audio on an FM radio; and
playing said audio on loudspeakers connected to said FM radio.

14. A method according to claim 13, further including the step of generating audio from said flash memory via an audio player adapted to MP3 or WMA formats.

15. A method according to claim 13, and including the step of powering said audio player via said plug.

16. A method according to claim 13, and including the step of charging a rechargeable battery of said audio player via said plug.

17. A method of playing compressed digital audio in a vehicle comprising the steps of:
coupling said audio to a transmitter;
transmitting said audio on the FM waveband;
receiving said audio on an in-car FM receiver; and
playing said audio on in-car speakers.

18. A method according to claim 17, and further including the step of converting said compressed digital audio to an analogue audio output, and coupling said output to said transmitter.
